(19) United States
(12) Patent Application Publication
(10) Pub. No.: US 2023/0403045 A1
(43) Pub. Date: Dec. 14, 2023

(54) ADAPTIVE FILTERS IN VEHICLE POWER LINE COMMUNICATION

(71) Applicant: GM Global Technology Operations LLC, Detroit, MI (US)

(72) Inventors: Shlomo Malka, Raanana (IL); Ayelet Aharon, Rishon Lezyon (IL); Igal Kotzer, Tel Aviv (IL)

(21) Appl. No.: 17/747,617

(22) Filed: May 18, 2022

(51) Int. Cl. H04B 3/54; H04L 67/12

(52) U.S. Cl. CPC H04B 3/542; H04L 67/12; H04B 3/548

(57) ABSTRACT

A power line communication (PLC) system in a vehicle includes one or more networks with one or more sub-networks of nodes interconnected by power lines that deliver direct current (DC) to the nodes. Each of the nodes is a controller or a sensor. The PLC system also includes one or more adaptive filters. Each of the one or more adaptive filters is coupled to a port of one of the nodes and dynamically changes a frequency range within which communication from and to the port of the one of the nodes over the power lines is possible.

The subject disclosure relates to adaptive filters in vehicle power line communication (PLC).

Vehicles (e.g., automobiles, trucks, motorcycles, construction equipment, farm equipment, automated factory equipment) include sensors and different hierarchical levels of controllers that communicate with each other. Power and communication lines may be routed in parallel among the different sensors and controllers. Accordingly, it is desirable to provide adaptive filters in vehicle PLC.

### SUMMARY

In one exemplary embodiment, a power line communication (PLC) system in a vehicle includes one or more networks with one or more sub-networks of nodes interconnected by power lines that deliver direct current (DC) to the nodes. Each of the nodes is a controller or a sensor. The PLC system also includes one or more adaptive filters. Each of the one or more adaptive filters is coupled to a port of one of the nodes and dynamically changes a frequency range within which communication from and to the port of the one of the nodes over the power lines is possible.

In addition to one or more of the features described herein, the PLC system also includes one or more basic filters attached at corresponding one or more locations of the power lines.

In addition to one or more of the features described herein, each of the one or more basic filters limiting communication through the basic filter to only communication below a specified frequency f0.

In addition to one or more of the features described herein, each of the one or more adaptive filters includes a basic filter component to limit communication through the basic filter to only communication below a specified frequency f0.

In addition to one or more of the features described herein, each of the one or more adaptive filters includes one or more bandpass filters. Each of the one or more bandpass filters limits communication to a specified range of frequencies.

In addition to one or more of the features described herein, each of the one or more bandpass filters of each of the one or more adaptive filters is coupled to a switch.

In addition to one or more of the features described herein, each of the one or more adaptive filters dynamically changes the frequency range within which communication from and to the port of the one of the nodes over the power lines is possible based on a control message communicated at a frequency below the specified frequency f0.

In addition to one or more of the features described herein, the control message controls the switch coupled to each of the one or more bandpass filters.

In addition to one or more of the features described herein, a central controller coupled to each of the one or more sub-networks of one of the one or more networks sends the control message.

In addition to one or more of the features described herein, a node sends the control message.

In another exemplary embodiment, a method of assembling a power line communication (PLC) system in a vehicle includes arranging one or more networks to include one or more sub-networks of nodes interconnected by power lines that deliver direct current (DC) to the nodes. Each of the nodes is a controller or a sensor. The method also includes arranging one or more adaptive filters. The arranging includes coupling each of the one or more adaptive filters to a port of one of the nodes and configuring each of the one or more adaptive filters to dynamically change a frequency range within which communication from and to the port of the one of the nodes over the power lines is possible.

In addition to one or more of the features described herein, the method also includes attaching one or more basic filters at corresponding one or more locations of the power lines.

In addition to one or more of the features described herein, the method also includes configuring each of the one or more basic filters to limit communication through the basic filter to only communication below a specified frequency f0.

In addition to one or more of the features described herein, the configuring the one or more adaptive filters includes each of the one or more adaptive filters including a basic filter component to limit communication through the basic filter to only communication below a specified frequency f0.

In addition to one or more of the features described herein, the configuring the one or more adaptive filters includes each of the one or more adaptive filters including one or more bandpass filters, each of the one or more bandpass filters limiting communication to a specified range of frequencies.

In addition to one or more of the features described herein, the method also includes coupling each of the one or more bandpass filters of each of the one or more adaptive filters to a switch.

In addition to one or more of the features described herein, the configuring the one or more adaptive filters includes each of the one or more adaptive filters dynamically changing the frequency range within which communication from and to the port of the one of the nodes over the power lines is possible based on a control message communicated at a frequency below the specified frequency f0.

In addition to one or more of the features described herein, the method also includes controlling the switch coupled to each of the one or more bandpass filters using the control message.

In addition to one or more of the features described herein, the method also includes coupling a central controller to each of the one or more sub-networks of one of the one or more networks and configuring the central controller to send the control message.

In addition to one or more of the features described herein, the method also includes configuring a node to send the control message.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a block diagram of a vehicle with adaptive filters in a power line communication (PLC) system according to one or more embodiments;

FIG. 2 details aspects of the PLC system according to one or more embodiments; and

FIG. 3 details aspects of an adaptive filter in a PLC system and dynamic configuration of the adaptive filter according to one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features.

Embodiments of the systems and methods detailed herein relate to adaptive filters in vehicle PLC. As previously noted, power and communication lines may be routed together among sensors and controllers according to a prior approach. The power lines route power, typically direct current (DC), to each sensor or controller and the communication lines route communication among the sensors and controllers. PLC refers to data communication via power lines of a vehicle (i.e., power line communication). Thus, by using PLC (i.e., data communication via power lines), the number of dedicated communication cables in the vehicle may be reduced. According to one or more embodiments detailed herein, PLC is not a mere replacement of communication cable standards via PLC. A hierarchical architecture coupled with the use of adaptive filters, as detailed, facilitates resource re-use through network separation.

Generally, the PLC architecture may involve two or more hierarchical levels and network partitions. For example, the power line originating from the battery of the vehicle may be split to two or more central controllers that each control a set of nodes. A given central controller may control two or more branches (i.e., sub-networks) and additional sub-branches of nodes. The nodes may be electronic control units (ECU)s, each of which control one or more electrical subsystems of the vehicle (e.g., powertrain, suspension, brake control), and sensors (e.g., camera, lidar system, radar system, ultrasonic sensor). Each central controller and node includes a PLC chipset (e.g., a microcontroller) with a modulator-demodulator (modem) to write data bits onto direct current (DC) wires or read data from the DC wires. In addition to basic filters that only allow communication within a shared message frequency range, adaptive filters at different locations of the branches or sub-branches facilitate flexible control over communication among the nodes. Specifically, the data rates or frequencies of communication that may pass through each adaptive filter may be controlled. This increases efficiency by ensuring that irrelevant data is not obtained at different nodes and allows the resources to be available for reuse.

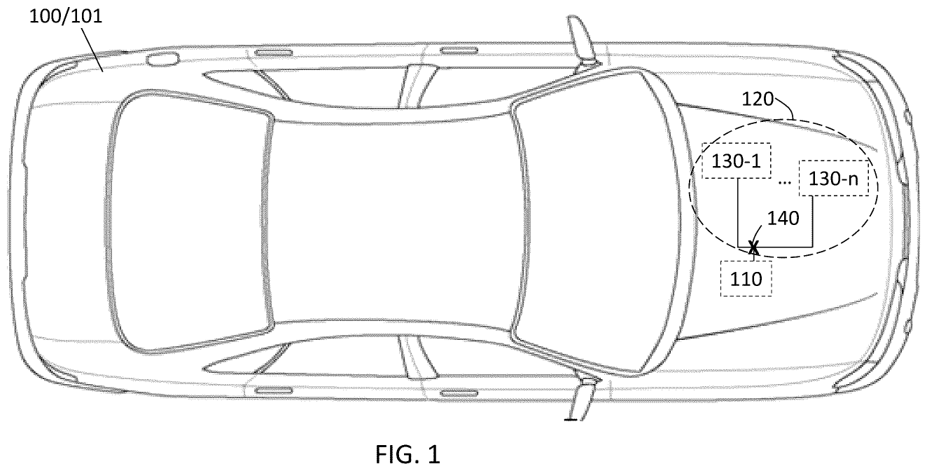

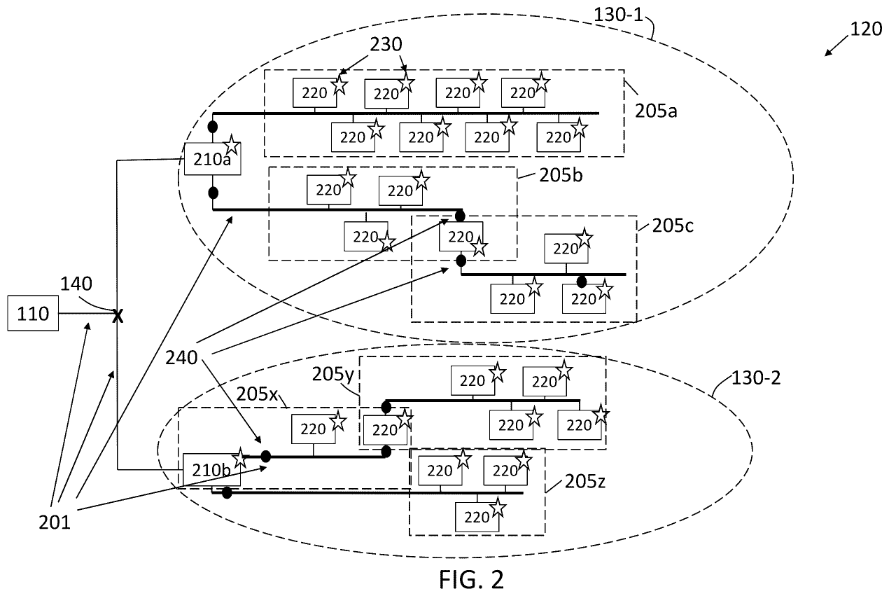

In accordance with an exemplary embodiment, FIG. 1 is a block diagram of a vehicle 100 with adaptive filters 240 (FIG. 2) in a PLC system 120. The exemplary vehicle 100 shown in FIG. 1 is an automobile 101. The vehicle 100 includes a battery 110 that powers the PLC system 120. As shown in FIG. 1 and further discussed with reference to FIG. 2, the PLC system 120 may include any number of networks 130-1 through 130-n (generally referred to as 130). A basic filter 140 is shown to provide separation among the networks 130. The basic filter 140 is attached (i.e., coupled) to the power line 201 at a point that connects the two networks 130-1 and 130-2 and acts to prevent communication, beyond shared communication, between them.

That is, the basic filter 140 is a low pass filter that only passes a set of frequencies f in a range (e.g., 0≤f≤f0) associated with DC and a low frequency range in which information is shared among the networks 130. The basic filter 140 prevents communication within one network 130 from reaching nodes 220 (FIG. 2) of another network 130 that do not need the information. As further discussed with reference to FIG. 2, the adaptive filters 240 provide additional flexibility and efficiency to the PLC system 120 by allowing more granular control over which nodes 220 communicate with each other. In addition, the adaptive filters 240 may be dynamically controlled via the shared communication.

FIG. 2 details aspects of the PLC system 120 according to one or more embodiments. Some of the power lines 201 that begin at the battery 110 and traverse the PLC system 120 to interconnect nodes 220 and to allow communication over the same wires that carry DC are indicated (all are not indicated for readability). The exemplary PLC system 120 is shown with two networks 130-1, 130-2 (generally 130) for explanatory purposes. However, any number of networks 130 and sub-networks 205 within the networks are contemplated. In addition, any number of nodes 220 may be part of each subnetwork 205. The first exemplary network 130-1 is shown to include three sub-networks 205a, 205b, 205c (generally referred to as 205) and the second exemplary network 130-2 is shown to include three sub-networks 205x, 205y, 205z (generally referred to as 205). The sub-networks 205c and 205y branch, respectively, from sub-networks 205b and 205x. Any number of such hierarchies may be present within a network 130.

Each network 130 includes a central controller 210a, 210b (generally referred to as 210) that is connected to the battery 110 and is a source of the DC for the network 130. As previously noted, the nodes 220 of each of the networks 130 may be ECUs that control one or more electrical subsystems of the vehicle or and sensors. The nodes 220 that are ECUs and at least some of the nodes 220 that are sensors and the central controller 210 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

As noted with reference to FIG. 1, a basic filter 140 may be used (e.g., attached to the power line 201) to isolate the networks 130-1 and 130-2 from each other. Specifically, only DC and messages generated at frequencies below frequency f0 (i.e., in a shared message frequency range) may pass between the two networks 130. Each central controller 210 and node 220 is shown with a star, which is used to designate a chipset 230 that includes the components, such as a modem, that facilitate the communication over the power lines 201. Every star that indicates the chipset 230 is not labeled for readability purposes.

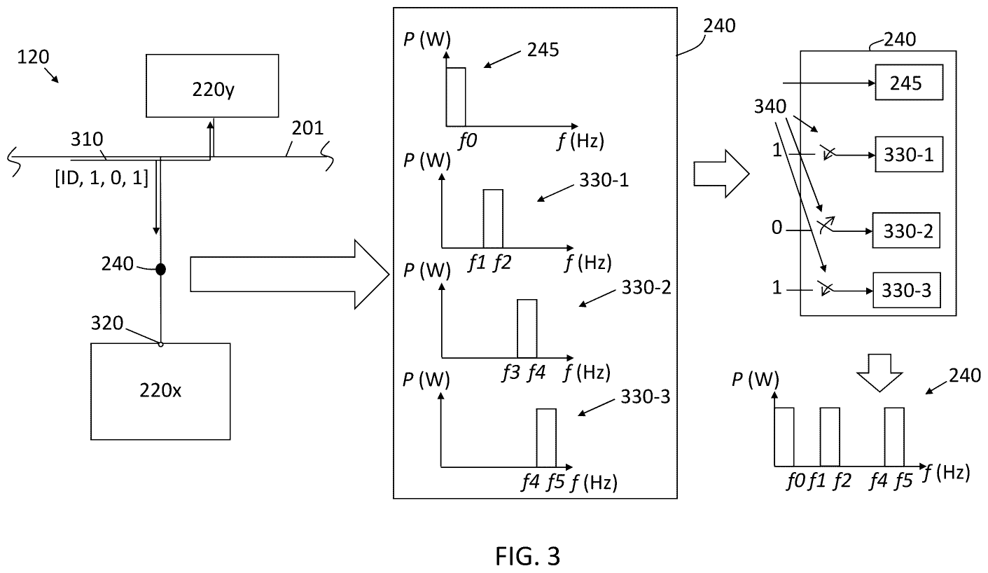

In addition to the basic filter 140, a number of adaptive filters 240 (indicated by black dots) may be used throughout the PLC system 120. While the basic filter 140 may be attached to the power line 201 (e.g., connecting networks or nodes), the adaptive filters 240 may be attached (i.e., coupled) at the ports 320 (FIG. 3) of nodes 220. Also, while the basic filter 140 is a low-pass filter that only passes frequencies f in a range (e.g., 0≤f≤f0), the adaptive filters 240 are a combination of the basic filter 140 (i.e., a low-pass filter) and one or more bandpass filters 330 (FIG. 3) that pass different frequency ranges. Thus, the adaptive filters 240, which are further discussed with reference to FIG. 3, support information exchange at different data rates (i.e., frequencies). In addition, the adaptive filters 240 are dynamically reconfigurable. The configuration of an adaptive filter 240 may be changed via a control message 310 that is provided in the shared message frequency range, as further discussed with reference to FIG. 3.

FIG. 3 details aspects of an adaptive filter 240 in a PLC system 120 and dynamic configuration of the adaptive filter 240 according to one or more embodiments. Part of a PLC system 120 is illustrated in FIG. 3, showing two nodes 220x and 220y that are supplied with DC via a power line 201. The exemplary node 220x has an adaptive filter 240 attached at a port 320. The exemplary node 220y has no adaptive filter 240 associated with it. Thus, the node 220y receives all communication (e.g., data, information) from the node 220x and via the power line 201 generally. An exemplary control message 310 [ID, 1, 0, 1] is shown and further discussed. For explanatory purposes, the identification (ID) in the control message 310 is an identity of the exemplary adaptive filter 240 at the port 320 of the node 220x. As indicated, the control message 310, which is in the shared message frequency range, reaches every part of the PLC system 120 including both nodes 220x, 220y.

The basic filter component 245 and three exemplary bandpass filters 330-1, 330-2, and 330-3 (generally 330) that make up the exemplary adaptive filter 240 are shown. The basic filter component 245 has an identical function to the basic filter 140. While three bandpass filters 330 are shown for the exemplary adaptive filter 240, any number of bandpass filters 330 and the basic filter component 245 may define a given adaptive filter 240. A frequency response of each of the filters 245, 330 that forms the exemplary adaptive filter 240 is shown. Power P in Watts (W) is indicated along one axis and frequency f in hertz (Hz) is shown on a perpendicular axis. As previously discussed for the basic filter 140, in the basic filter component 245, only frequencies f below f0 are passed (i.e., the output power P at frequencies f above frequency f0 is 0). Each of the bandpass filters 330 has a range of frequencies f that are passed, while all communication at frequencies f outside the specified range are not. The pass band for bandpass filter 330-1 is between the frequencies f1 and f2, the pass band for the bandpass filter 330-2 is between f3 and f4, and the pass band for the bandpass filter 330-3 is between f4 and f5.

The correspondence between the exemplary control message 310 and switches 340 associated with each of the bandpass filters 330 is shown. The [1, 0, 1] in the exemplary control message 310 indicates that the switch 340 associated with the bandpass filter 330-1 should be closed (i.e., the bandpass filter 330-1 should be enabled, namely signals will pass through the filter and be band limited because the bandpass filter 330-1 will act as a filter), the switch 340 associated with the bandpass filter 330-2 should be open (i.e., the bandpass filter 330-2 should be disabled, namely signals will not pass through the filter and be band limited), and the switch 340 associated with the bandpass filter 330-3 should be closed (i.e., the bandpass filter 330-3 should be closed, namely signals will pass through the filter and be band limited). No switch 340 is associated with the basic filter component 245, which cannot be disabled. The frequency response of the exemplary adaptive filter 240 based on the exemplary control message 310 is shown. Specifically, only communication in the frequency ranges from 0 to f0, from f1 to f2, and from f4 to f5 will enter the power line 201 from the node 220x or will reach the node 220x from the power line 201.

If the node 220x exhibits a malfunction that is detected by the central controller 210 of the network 130 in which the node 220x resides or by another node 220 (e.g., an ECU), then all of the bandpass filters 330 of the adaptive filter 240 may be disabled (e.g., control message 310 may includes [0, 0, 0]). In this case, only messages in the shared message frequency range (i.e., frequencies f below f0) according to the basic filter component 245 of the adaptive filter 240 may be sent from or received by the node 220x. Thus, adaptive filters 240 may be added at ports 320 of all nodes 220 that are known to be problematic or prone to malfunction, for example.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

1. A power line communication (PLC) system in a vehicle, the PLC system comprising:
a hierarchical PLC architecture including multiple hierarchical levels having one or more networks on a first level partitioned into one or more sub-networks of nodes on second levels interconnected by power lines that deliver direct current (DC) to the nodes, wherein each of the nodes is a controller or a sensor;
one or more adaptive filters, each of the one or more adaptive filters including a basic filter component and one or more bandpass filters, each of the one or more adaptive filters being coupled to a port of one of the nodes in the sub-networks of nodes on second levels and being configured to dynamically change a frequency range within which communication from and to the port of the one of the nodes over the power lines is enabled; and
wherein at least one of the adaptive filters is configured to respond to a malfunction at the one of the nodes in the sub-network of nodes to which port the adaptive filter is connected by disabling each band pass filter within the adaptive filter connected to the port of the one of the nodes experiencing the malfunction.

2. The PLC system according to claim 1, further comprising one or more basic filters attached at corresponding one or more locations of the power lines.

3. The PLC system according to claim 2, wherein each of the one or more basic filters limiting communication through the basic filter to only communication below a specified frequency f0.

4. The PLC system according to claim 1, wherein each basic filter component is configured to limit communication through the basic filter to only communication below a specified frequency f0.

5. The PLC system according to claim 4, wherein each of the one or more bandpass filters is configured to limit communication to a specified range of frequencies.

6. The PLC system according to claim 5, wherein each of the one or more bandpass filters of each of the one or more adaptive filters is coupled to a switch.

7. The PLC system according to claim 6, wherein each of the one or more adaptive filters is configured to dynamically change the frequency range within which communication from and to the port of the one of the nodes over the power lines is possible based on a control message communicated at a frequency below the specified frequency f0.

8. The PLC system according to claim 7, wherein the control message controls the switch coupled to each of the one or more bandpass filters.

9. The PLC system according to claim 7, wherein a central controller coupled to each of the one or more sub-networks of one of the one or more networks is configured to send the control message.

10. The PLC system according to claim 7, wherein a node is configured to send the control message.

11. A method of assembling a power line communication (PLC) system in a vehicle, the method comprising:
arranging a hierarchical PLC architecture including multiple hierarchical levels comprising one or more networks on a first level partitioned into one or more sub-networks of nodes on second levels interconnected by power lines that deliver direct current (DC) to the nodes, wherein each of the nodes is a controller or a sensor; and
arranging one or more adaptive filters, each of the one or more adaptive filters including a basic filter component and one or more bandpass filters, wherein the arranging includes coupling each of the one or more adaptive filters to a port of one of the nodes in the sub-networks of nodes on second levels and configuring each of the one or more adaptive filters to dynamically change a frequency range within which communication from and to the port of the one of the nodes over the power lines is enable; and
wherein at least one of the adaptive filters is configured to respond to a malfunction at the one of the nodes in the sub-network of nodes to which port the adaptive filter is connected by disabling each band pass filter within the adaptive filter connected to the port of the one of the nodes experiencing the malfunction.

12. The method according to claim 11, further comprising attaching one or more basic filters at corresponding one or more locations of the power lines.

13. The method according to claim 12, further comprising configuring each of the one or more basic filters to limit communication through the basic filter to only communication below a specified frequency f0.

14. The method according to claim 11, wherein each of the basic filter components limit communication through the basic filter to only communication below a specified frequency f0.

15. The method according to claim 14, wherein each of the one or more bandpass filters limits communication to a specified range of frequencies.

16. The method according to claim 15, further comprising coupling each of the one or more bandpass filters of each of the one or more adaptive filters to a switch.

17. The method according to claim 16, wherein the configuring the one or more adaptive filters includes each of the one or more adaptive filters dynamically changing the frequency range within which communication from and to the port of the one of the nodes over the power lines is possible based on a control message communicated at a frequency below the specified frequency f0.

18. The method according to claim 17, further comprising controlling the switch coupled to each of the one or more bandpass filters using the control message.

19. The method according to claim 17, further comprising coupling a central controller to each of the one or more sub-networks of one of the one or more networks and configuring the central controller to send the control message.

20. The method according to claim 17, further comprising configuring a node to send the control message.
